(19) United States
(12) Patent Application Publication
(10) Pub. No.: US 2023/0207568 A1
(43) Pub. Date: Jun. 29, 2023

(54) Semiconductor Device and Method for Power MOSFET on Partial SOI

(71) Applicant: IceMos Technology Limited, Belfast (GB)

(72) Inventors: Takeshi Ishiguro, Fukushima (JP); Samuel J. Anderson, Tempe, AZ (US); Aymeric Privat, Tempe, AZ (US)

(73) Assignee: IceMos Technology Limited, Belfast (GB)

(21) Appl. No.: 18/069,815

(22) Filed: Dec. 21, 2022

Related U.S. Application Data
(60) Provisional application No. 63/265,980, filed on Dec. 23, 2021.

(51) Int. Cl. H01L 27/12; H01L 21/84

(52) U.S. Cl. CPC H01L 27/1207; H01L 21/84

(57) ABSTRACT

A power transistor has a plurality of cells, each cell having a notch formed in a substrate. An insulating material, such as an oxide, is formed within the notch. A semiconductor layer is formed over the substrate and insulating material. The semiconductor layer has a first type of semiconductor material and a second type of semiconductor material opposite the first type of semiconductor material to form the power transistor. A width of the insulating material within the notch is less than a width of the semiconductor layer so that a portion of the substrate extends to the semiconductor layer. The notch can have a slope or a step. The insulating material has a first thickness and a second thickness greater than the first thickness within the notch. The insulating material may extend completely across the interface between substrate and semiconductor layer, or only partially across the interface.

### CLAIM TO DOMESTIC PRIORITY

The present application claims the benefit of U.S. Provisional Application No. 63/265,980, filed Dec. 23, 2021, which application is incorporated herein by reference.

### FIELD OF THE INVENTION

The present invention relates in general to a semiconductor device and, more particularly, to a semiconductor device and method of forming a power MOSFET on partial SOI.

### BACKGROUND OF THE INVENTION

Semiconductor devices are commonly found in modern electrical products. Semiconductor devices vary in the number and density of electrical components. Discrete semiconductor devices generally contain one type of electrical component, e.g., a light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, interface circuits, and other signal processing circuits.

Semiconductor devices perform a wide range of functions, such as signal processing, high-speed calculations, transmitting and receiving electromagnetic signals, controlling electrical devices, transforming sunlight to electricity, and creating visual projections for television displays. Semiconductor devices are found in the fields of communications, power conversion, networks, computers, and consumer products. Semiconductor devices are also found in military applications, aerospace, aviation, automotive, data processing centers, industrial controllers, and office equipment.

MOSFETs are commonly used in electrical circuits, such as communication systems and power supplies. Power MOSFETs are particularly useful when used as electric switches to enable and disable the conduction of relatively large currents. The on/off state of the power MOSFET is controlled by applying and removing a triggering signal at the gate electrode. When turned on, the electric current in the MOSFET flows between the drain and source. When turned off, the electric current is blocked by the MOSFET.

The power MOSFET is typically arranged in an array of thousands of individual MOSFET cells electrically connected in parallel. The MOSFET cell has an inherent drain-source resistance per unit area (RONA) in the conducting state. The width of the MOSFET cell influences the electrical resistance of the MOSFET cell. The larger the cell width, the larger the resistance. Conversely, the larger the cell density with corresponding smaller cell width, the smaller the resistance. Design goals include minimizing RONA, minimizing output capacitance C_{OSS}, and maximizing breakdown voltage. Yet there are often trade-offs between these design goals, leading to a need for design flexibility in focusing on one or more of these goals.

### BRIEF DESCRIPTION OF THE DRAWINGS

FIG. 1 illustrates a block diagram of a power supply and electrical equipment;

FIG. 2 is a schematic and block diagram of a pulse width modulated power supply;

FIG. 3 illustrates a semiconductor wafer with a plurality of semiconductor die;

FIGS. 4a-4k illustrate a process of forming a multi-cell power MOSFET with a buried oxide material;

FIG. 5 is a waveform plot of output capacitance C_{OSS} versus V_{DS} for various buried oxide thicknesses;

FIG. 6 is another waveform plot of C_{OSS} versus V_{DS} for various buried oxide thicknesses;

FIG. 7 is a waveform plot of RONA and breakdown voltage versus buried oxide thickness;

FIG. 8 is a waveform plot of RONA and breakdown voltage versus N-region doping concentration;

FIG. 9 is a waveform plot of C_{OSS} versus V_{DS} for various N-region doping concentrations;

FIG. 10 illustrates a power MOSFET cell with buried oxide material and surface P region;

FIG. 11 is a waveform plot of C_{OSS} versus V_{DS} for FIGS. 4i and 10;

FIG. 12 illustrates a power MOSFET cell with a buried oxide material extending across the entire cell;

FIG. 13 illustrates a power MOSFET cell with a buried oxide material having a linear slope;

FIG. 14 illustrates a power MOSFET cell with a buried oxide material with a step between a first thickness and a second thickness;

FIG. 15 illustrates a power MOSFET cell with buried oxide material with a step between a first thickness and a second thickness extending across the cell;

FIGS. 16a-16b illustrate forming the buried oxide material having a linear slope in FIG. 13;

FIGS. 17a-17b illustrate forming the buried oxide material having the step in FIG. 14;

FIGS. 18a-18b illustrate forming the buried oxide material having the step in FIG. 15;

FIGS. 19a-19d illustrate another process of forming the buried oxide material having the step in FIG. 15;

FIG. 20 is a waveform plot of C_{OSS} versus V_{DS} for FIGS. 4i and 13-15;

FIG. 21 is a waveform plot of C_{OSS} versus V_{DS} for no buried oxide material and FIGS. 4i; and

FIG. 22 is a waveform plot of C_{OSS} versus V_{DS} for no buried oxide material and FIGS. 14.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Most modern electrical equipment requires a power supply to provide a DC operating potential to the electrical components contained therein. Common types of electrical equipment which use power supplies include aerospace, personal computers, energy systems, telecommunication systems, audio-video equipment, consumer electrical devices, automotive components, portable electrical devices, data processing centers, LED lighting, electric vehicles, and other devices which utilize integrated circuits, semiconductor chips, or otherwise require DC operating potential. Many semiconductor components require a low voltage DC operating potential. However, many sources of electric power are AC, or high voltage DC, which must be converted to low voltage DC for the electrical equipment.

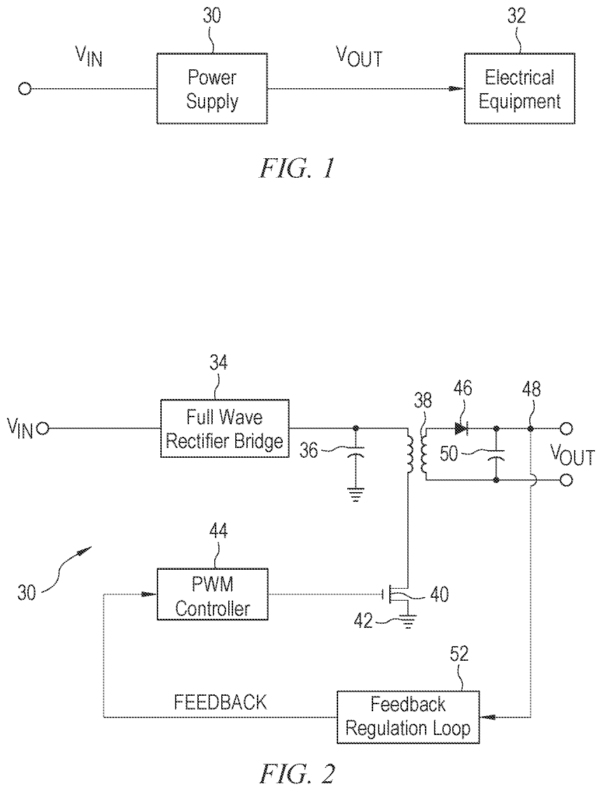

In one common arrangement, the AC/DC power supply receives an AC input voltage, e.g., between 110 and 220 VAC, and converts the AC input voltage to the DC operating voltage. Referring to FIG. 1, a PWM power supply 30 is shown providing a DC operating potential to electrical equipment 32. Power supply 30 receives input voltage V_{IN} and produces one or more DC output voltages. The electrical equipment 32 may take the form of aerospace equipment, personal computers, energy systems, telecommunication systems, audio-video equipment, consumer electrical devices, automotive components, portable electrical devices, aerospace, data processing centers, LED lighting, charging stations for electric vehicles, variable speed drives for electric motors, and other devices which utilize integrated circuits, semiconductor chips, or otherwise require DC operating potential from the power supply.

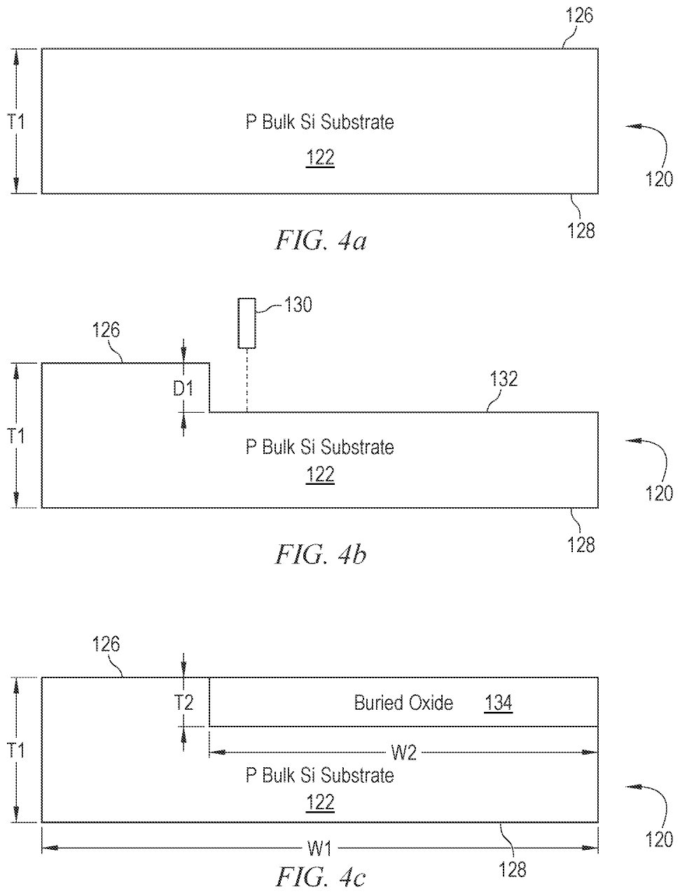

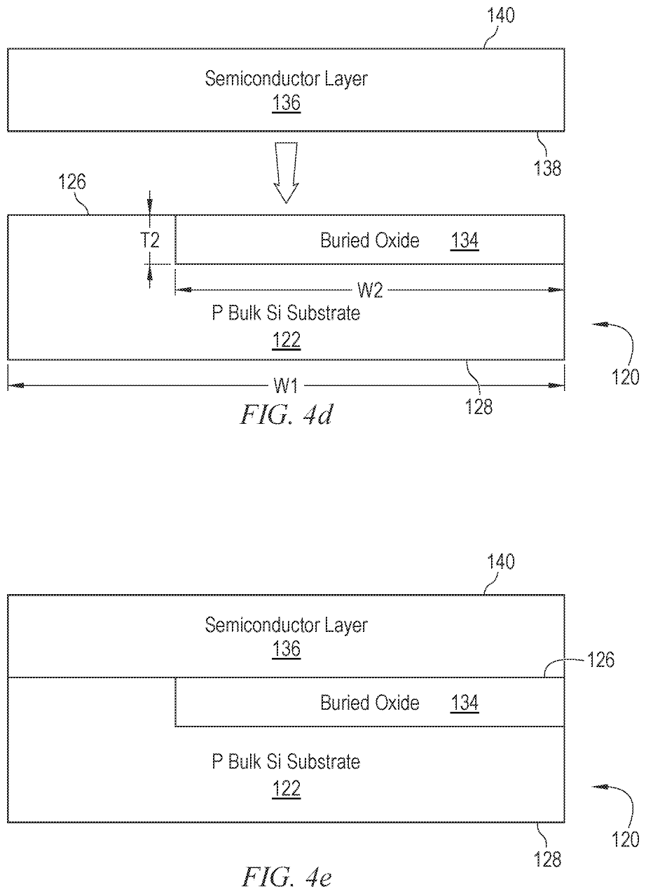

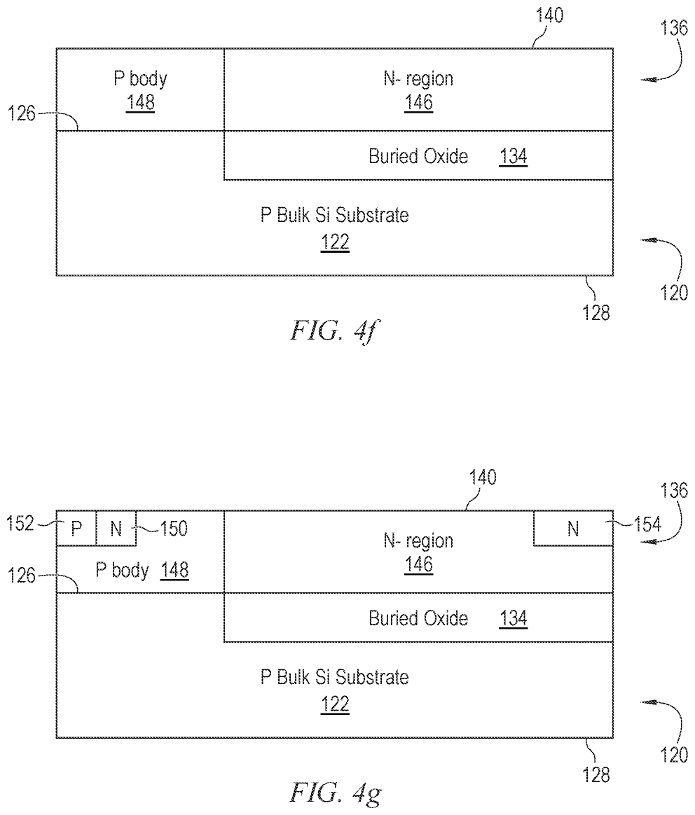

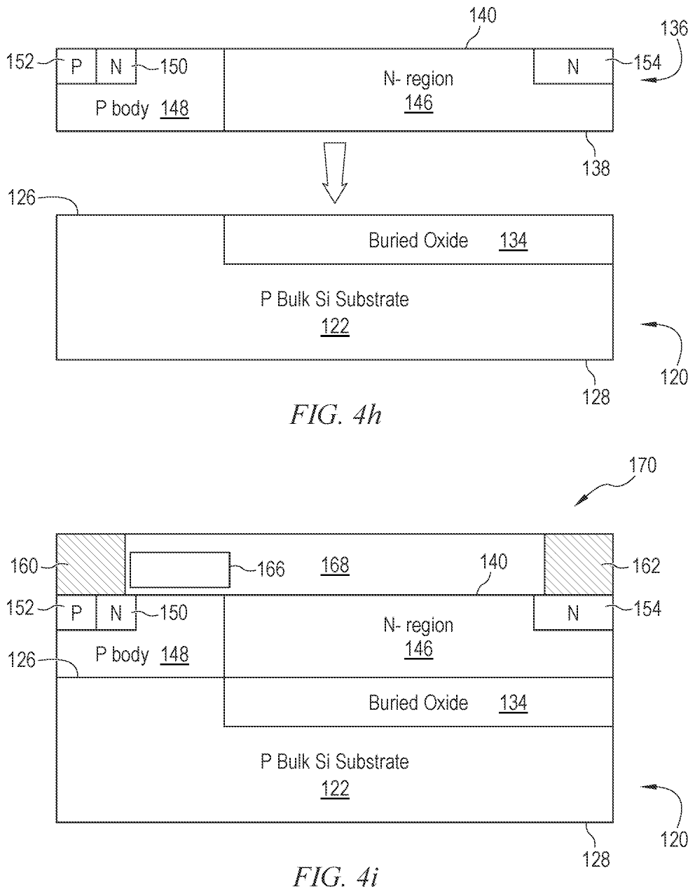

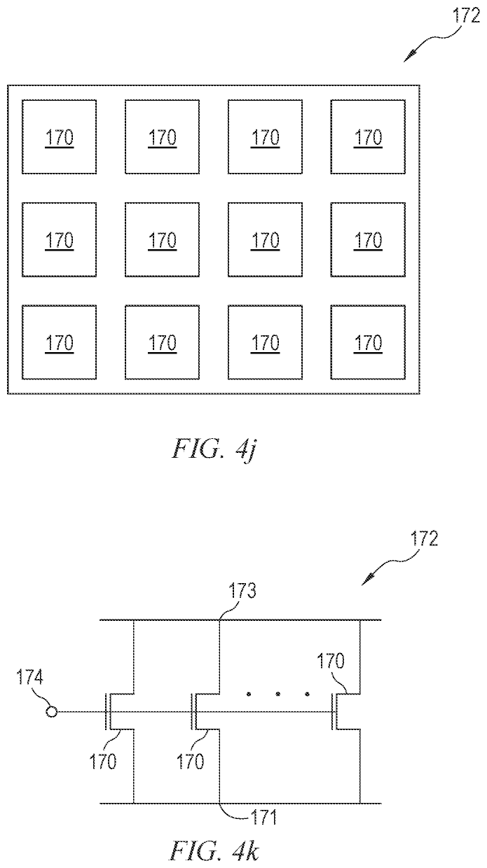

Further detail of PWM power supply 30 is shown in FIG. 2. The input voltage V_{IN} may be an AC signal, e.g., 110 VAC, or DC signal, e.g., 48 volts. For the case of an AC input voltage, power supply 30 has a full-wave rectifier bridge 34. The full-wave rectifier bridge 34 converts the AC input voltage to a DC voltage. In the case of a DC input voltage, the full-wave rectifier bridge 34 is omitted. Capacitor 36 smooths and filters the DC voltage. The DC voltage is applied to a primary winding or inductor of transformer 38. The primary winding of transformer 38 is also coupled through power transistor 40 to ground terminal 42. In one embodiment, power transistor 40 is a multi-cell lateral power MOSFET, as described in FIGS. 4a-4k. The gate of MOSFET 40 receives a PWM control signal from PWM controller 44. The secondary winding of transformer 38 is coupled to rectifier diode 46 to create the DC output voltage V_{OUT} of power supply 30 at node 48. Capacitor 50 filters the DC output voltage V_{OUT}. The DC output voltage V_{OUT} is routed back through feedback regulation loop 52 to a control input of PWM controller 44. The DC output voltage V_{OUT} generates the feedback signal which PWM controller 44 uses to regulate the power conversion process and maintain a relatively constant output voltage V_{OUT} under changing loads. The aforedescribed electrical components of the power supply module are typically mounted to and electrically interconnected through a printed circuit board.

In the power conversion process, PWM controller 44 sets the conduction time duty cycle of MOSFET 40 to store energy in the primary winding of transformer 38 and then transfer the stored energy to the secondary winding during the off-time of MOSFET 40. The output voltage V_{OUT} is determined by the energy transfer between the primary winding and secondary winding of transformer 38. The energy transfer is regulated by PWM controller 44 via the duty cycle of the PWM control signal to MOSFET 40. Feedback regulation loop 52 generates the feedback signal to PWM controller 44 in response to the output voltage V_{OUT} to set the conduction time duty cycle of MOSFET 40.

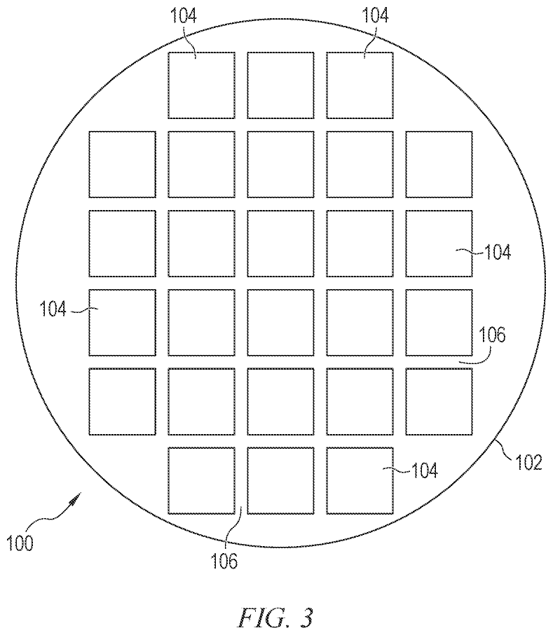

FIG. 3 shows semiconductor wafer or substrate 100 with a base substrate material 102, such as silicon (Si), SiC, cubic silicon carbide (3C-SiC), germanium, aluminum phosphide, aluminum arsenide, gallium arsenide, gallium nitride, indium phosphide, diamond, and all families of III-V and II-VI semiconductor materials for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

Semiconductor die 104 can be a lateral power MOSFET with gate, source, and drain terminals on a first surface of the die. Semiconductor die 104 can be contained in a semiconductor package, such as TO220, T0247, decawat package (DPAK), double decawat package (D2PAK), TSON, micro leadframe package (MLP), dual flat no-leads (DFN), and other packages for lateral and vertical discrete devices or lateral chip scale up-drain packages.

In the present embodiment, semiconductor die 104 contains a power MOSFET, applicable to MOSFET 40, with enhanced features to optimize RONA, output capacitance C_{OSS}, and/or breakdown voltage (BV). FIGS. 4a-4k illustrate a process of forming one lateral cell of MOSFET with partial silicon on insulator (SOI). FIG. 4a illustrates substrate 120 containing a base semiconductor material 122, such as Si, SiC, 3C-SiC, germanium, aluminum phosphide, aluminum arsenide, gallium arsenide, gallium nitride, indium phosphide, diamond, and all families of III-V and II-VI semiconductor materials for structural support.

Semiconductor substrate 120 is doped to change the physical and electrical characteristics of the material. Doping is the intentional introduction of impurities (dopant) into the lattice structure of an intrinsic semiconductor material (equal numbers of free electrons and holes) for the purpose of modulating its electrical, optical, physical, and structural properties. The doped material becomes an extrinsic semiconductor material. The doping is said to be low or light, given one dopant atom per 100 million (1e8) atoms, or 5e14 dopant atoms/cm³. The doping is referred to as high or heavy, given one dopant atom per ten thousand (1e4) atoms, or 5e18 dopant atoms/cm³. The dopant can be n-type material or p-type material, depending on the type of semiconductor device being made. Power MOSFET 172 can be an n-channel device (N-MOS) or a p-channel device (P-MOS), where “p” denotes a positive carrier type (hole) and “n” denotes a negative carrier type (electron).

In various implantation and diffusion steps described herein, the doping is performed by an initial ion implantation, solid diffusion, liquid diffusion, drive-in diffusion, spin-on deposits, plasma doping, vapor phase doping, laser doping, or the like to deposit impurities into the lattice structure of the region or layer. Doping with boron (B), aluminum (Al), or gallium (Ga) results in a more p-type region, and doping with phosphorus (P), antimony (Sb), or arsenic (As) impurities results in a n-type region. Other dopants may be utilized, such as bismuth (Bi) and indium (In), depending on the material of the substrate and the desired strength of the doping. First, the impurity is implanted in the surface of the intrinsic material, e.g., by ion implantation. After implantation of impurities at the surface, a drive-in diffusion step is typically required to disperse or distribute the impurities throughout the lattice structure of the layer or region. For example, following implantation of the dopant, a drive-in step at a temperature of 1200° C. for up to 12 hours. To minimize repetitive text, doping or doped refers to both the initial implanting of impurities and driving in or distributing the impurities to the lattice structure. In one embodiment, substrate 120 is doped with p-type material, such as B, Al, or Ga, in a concentration of 1e14 atoms/cm³. P bulk Si substrate 120 includes a first surface 126 and second surface 128 opposite the first surface 126 and thickness T1 of about 350 micrometers (μm).

FIG. 4b shows a portion of substrate 120 associated with one cell of the lateral power MOSFET. The width W1 of one lateral cell is about 6.75 μm. With respect to the noted one-cell region of substrate 120, a portion of base semiconductor material 122 is removed from surface 126 by etching or laser direct ablation (LDA) using laser 130. The removal of base semiconductor material 122 forms notch or recessed area 132 to a depth D1 of 1.0-5.0 μm, preferably 2.0 μm.

In FIG. 4c, insulating material 134 is formed within recessed area 132 of substrate 120. Insulating materials, as described herein, can be silicon dioxide (SiO2), silicon nitride (Si3N4), silicon oxynitride (SiON), tantalum pentoxide (Ta2O5), aluminum oxide (Al2O3), polyimide, benzocyclobutene (BCB), polybenzoxazoles (PBO), or other suitable insulating or dielectric material formed using PVD, CVD, screen printing, spin coating, spray coating, sintering, or thermal oxidation. The top surface of insulating material 134 is co-planar with surface 126. In one embodiment, insulating material 134 is a buried oxide material having width W2 of 5.5 μm and thickness T2 of 1.0-5.0 μm, preferably 2.0 μm. The terms insulating material 134 and oxide material are used interchangeably.

In FIG. 4d, semiconductor layer or wafer 136 is positioned over surface 126 of substrate 120 for bonding. Surface 138 of semiconductor layer 136 and surface 126 of substrate 120 are planarized, polished, and cleaned to be flat and smooth, prior to bonding. The lattice structures of semiconductor layer 136 and substrate 120 can be aligned to optimize adhesion. Surface 138 of semiconductor layer 136 is brought into contact with surface 126 of substrate 120. In FIG. 4e, semiconductor layer 136 is joined to substrate 120 using a high temperature anneal, fusion bonding, plasma activated direct wafer bonding (DWB), or other DWB process. Water molecules can be applied to surfaces 126 and 138 to aid in the bonding process. DWB is accomplished with chemical bonds and intermolecular interactions at temperature, including van der Waals forces, hydrogen bonds, and covalent bonds, between surface 138 and surface 126. DWB temperatures range from ambient to 100's ° C.

In FIG. 4f, surface 140 of semiconductor layer 136 is doped with n-type impurities, e.g., P, Sb, or As, at 1.5e16 atoms/cm³ for 30V, to form an N-region 146 within semiconductor layer 136, with a thickness dependent on design breakdown voltage. The breakdown voltage is determined by total amount of charge in N-region and field effect by p-substrate through the buried oxide material. When N-region 146 doping concentration is high, thickness must be reduced and vice versa. For example, the N-region 146 thickness is 0.5 μm for 100V breakdown voltage.

Surface 140 of semiconductor layer 136 is further implanted with a p-type impurity, such as B, Al, or Ga. The implant is performed at an energy level of about 30-200 kilo-electron-volts (KeV) with a dose between 1e16 and 1e18 atoms/cm³, preferably 1e17 atoms/cm³. The p-type impurities are driven-in, at a temperature of 900° C. for 10-30 minutes, to form P body 148. The width W2 of recessed area 132 and correspondingly insulating material 134 is less than the width W1 of semiconductor layer 136 within cell 170. In other words, insulating material 134 extends less than the width of semiconductor layer 136 for one cell 170 and a portion of P bulk substate 120 extends to P body 148 within the cell, as shown in FIG. 4f. N-region 146 remains isolated from P bulk substrate 120 by insulating material 134.

In FIG. 4g, surface 140 of p body 148 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form N source region 150.

P body 148 is implanted with a p-type impurity, such as B, Al, or Ga. The implant is performed at an energy level of about 30-200 KeV with a dose between 1e19 and 1e20 atoms/cm³. The p-type impurities are driven-in, at a temperature of 850° C. for 10 minutes, to form P contact 152.

N-region 146 is implanted with an n-type impurity, such as P, Sb, or As. The implant is performed at an energy level of about 30-200 KeV with a dose of 1e20 atoms/cm³. The n-type impurities are driven-in, at a temperature of 900° C. for 60 minutes, to form N drain region 154.

In another embodiment, semiconductor wafer or layer 136 can be implanted with relevant dopants to form N-region 146, P body 148, N source region 150, P contact 152, and N drain region 154, prior to joining the semiconductor layer to substrate 120. FIG. 4h shows semiconductor layer 136 doped with impurities, as described in FIGS. 4f-4g, to form N-region 146, P body 148, N source region 150, P contact 152, and N drain region 154, prior to joining the semiconductor layer to substrate 120. After doping, the semiconductor layer 136 is then joined to substrate 120, as described in FIG. 4d-4e. The resulting structure is similar to FIG. 4g.

In FIG. 4i, conductive layer 160 is formed over P contact 152 and N source region 150, and conductive layer 162 is formed over N drain region 154. Conductive layers 160-162 are formed using PVD, CVD, electrolytic plating, electroless plating process, or other suitable metal deposition process. Conductive layers 160-162 can be one or more layers of Al, Cu, Sn, Ni, Au, Ag, or other suitable electrically conductive material. Polysilicon material 166 is formed over P body 148 as the gate structure over the channel region. Insulating material 168 is formed over a portion of N source region 150, P body 148, N-region 146, and N drain region 154. Insulating material 168 is further formed over and around polysilicon material 166 to isolate the gate structure from the channel region. In one embodiment, a first portion of insulating material 168 is formed over P body 148, followed by polysilicon material 166, and then a top layer of additional insulating material.

FIG. 4i shows one cell 170 of lateral power MOSFET 172 with source 150, gate 166, and drain 154 formed on surface 110 of semiconductor die 104. FIG. 4j shows multiple cells 170 of lateral power MOSFET 172, where multiple cells 170 are connected in parallel, i.e., common sources, common drains, and common gates, for high current carrying capacity. FIG. 4k is a schematic representation of multiple cells 170 connected in parallel, i.e., common source 171, common drain 173, and common gate 174, for high current carrying capacity. A high voltage applied to common gate 174 causes current to flow simultaneously drain to source in each cell 170. The sum total of current in all cells 170 is the total drain-source current of power MOSFET 172. Power MOSFET 172 is applicable to power transistor 40. Other semiconductor devices can be formed in semiconductor layer 136, such as a diode or insulated gate bipolar transistor.

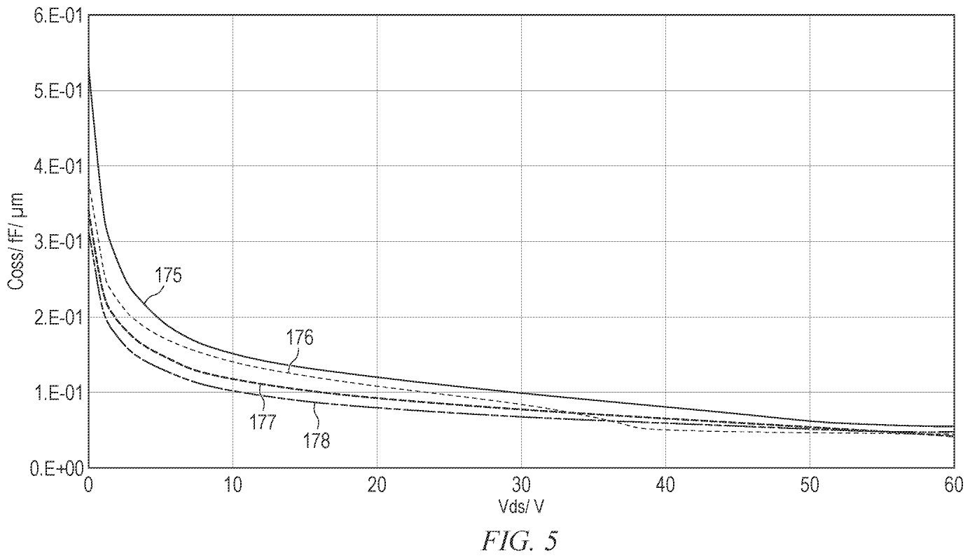

Power MOSFET 172 has an associated C_{OSS}, breakdown voltage, and RONA. FIG. 5 illustrates a graph of C_{OSS}, over a range of V_{DS}, for a variety of thicknesses of insulting layer 134 in FIG. 4i. Waveform 175 is for zero thickness of insulating material 134, i.e., no buried oxide material, waveform 176 is for 1.0 μm of insulating material 134, waveform 177 is for 5.0 μm of insulating material 134, and waveform 178 is for 2.0 μm of insulating material 134. Output capacitance C_{OSS} decreases for embodiments having a minimum thickness of insulating material 134. In one embodiment, the optimal thickness is 1.0-2.0 μm. Waveform 178 shows a 2.0 μm thickness of insulating material 134 has minimum C_{OSS} for less than about 35V V_{DS}, and waveform 176 shows a 1.0 μm thickness of insulating material 134 has minimum C_{OSS} for greater than about 35V V_{DS}. A thickness of insulating material 134 in excess of the optimal value tends to increase C_{OSS}. The decrease in C_{OSS} can be attributed to small dielectric constant of oxide (smaller than Silicon) and field effect by P bulk substrate 120. When oxide is thin, field effect by P bulk substrate 120 is greater, but oxide capacitance is large. When oxide is thick, field effect by P bulk substrate 120 is less, but oxide capacitance is small. Thus, in both cases, field effect by P bulk substrate 120 and oxide capacitance are in competitive relationship. A thickness of 2.0 μm of oxide would be well-balanced for field effect and oxide capacitance in this case.

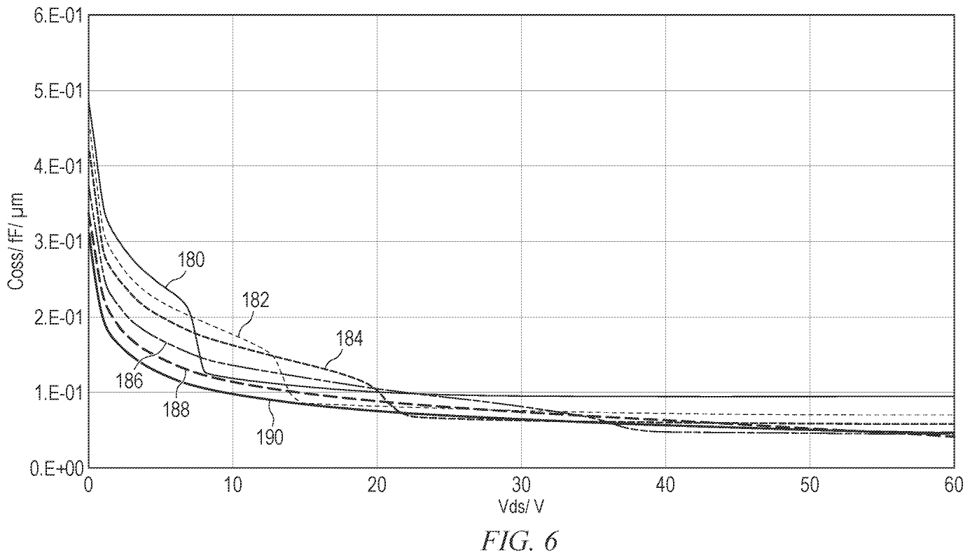

FIG. 6 illustrates a graph of C_{OSS}, over a range of V_{DS}, with a wider range of thicknesses for insulting layer 134 in FIG. 4i. Waveform 180 is for 0.1 μm thickness of insulating material 134, waveform 182 is for 0.3 μm of insulating material 134, waveform 184 is for 0.5 μm of insulating material 134, waveform 186 is for 1.0 μm of insulating material 134, waveform 188 is for 2.0 μm of insulating material 134, and waveform 190 is for 5.0 μm of insulating material 134. Again, output capacitance C_{OSS} decreases for embodiments having a minimum thickness of insulating material 134. Full depletion effect is more significant when the buried oxide material is thin. The thinner oxide, the lower C_{OSS} drop voltage. So, with this effect, thinner buried oxide material shows lower C_{OSS} than that of thicker buried oxide material in certain regions. For example, between about 8V to 20V, C_{OSS} of waveform 180 is smaller than that of waveform 186. However, full depletion effect is less than thick oxide effect. Therefore, overall C_{OSS} is smaller for thick buried oxide material.

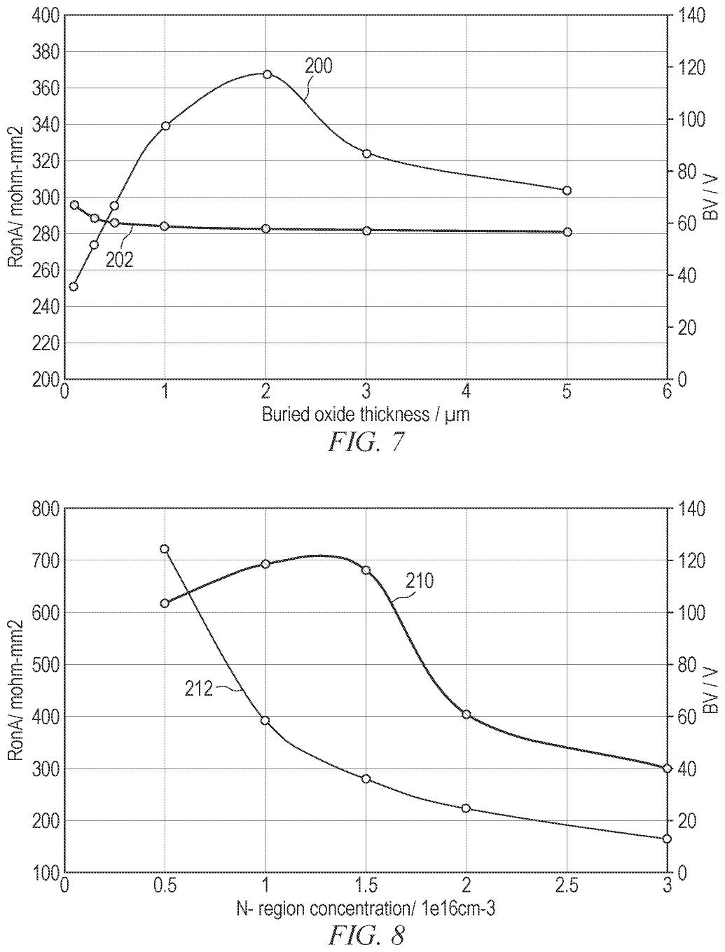

FIG. 7 illustrates a graph of RONA and breakdown voltage, over a range of buried oxide thickness. Waveform 200 is breakdown voltage, and waveform 202 is RONA. Breakdown voltage and RONA also vary with oxide thickness. When insulating material 134 is thin, N-region 146 is readily depleted even at low drain-source voltage V_{DS}, RONA increases. At the same time, when insulating material 134 is thin, higher V_{DS} causes inversion in N-region 146, leading to a low breakdown voltage which is dominated by drain N and inversion layer. On the other hand, when buried oxide material is thick, source edge of N-region 146 is not depleted, causing lower breakdown. Therefore, in any case, doping concentration of N-region 146 is optimized by making the concentration higher or lower or gradation between drain and source, providing higher RONA. The highest breakdown voltage and lowest C_{OSS} is achieved with a 2.0 μm thickness of insulating material 134 and N-region 146 doping concentration of 1.0e16 to 1.5e16 atoms/cm³.

FIG. 8 illustrates a graph of RONA and breakdown voltage, over a range of N-region 146 concentration. Waveform 210 is breakdown voltage, and waveform 212 is RONA. Increasing N-region 146 concentration, decreases RONA and maximum BV is given when N-region 146 concentration is 1.0e16 to 1.5e16 atoms/cm³.

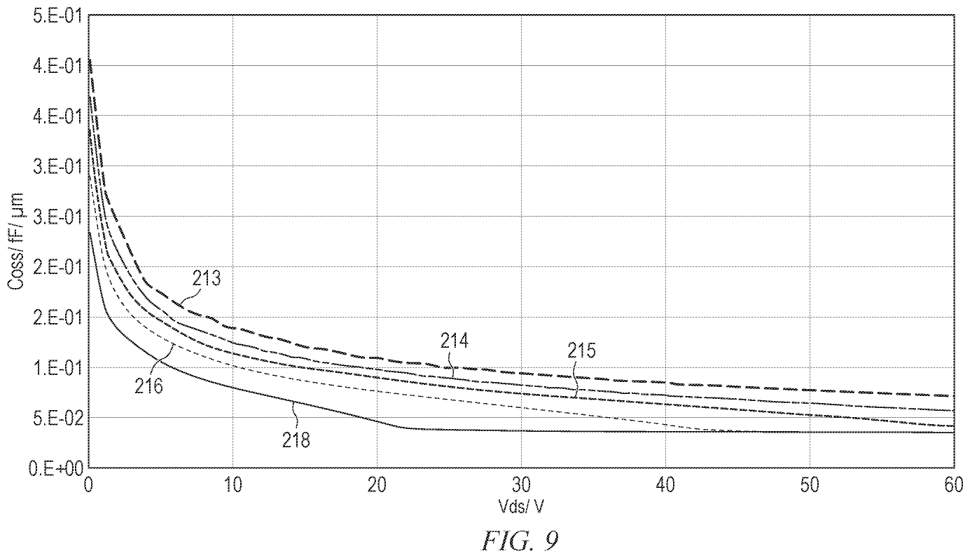

FIG. 9 illustrates a graph of C_{OSS}, over a range of V_{DS}. Waveform 213 is for N-region 146 doping concentration of 3e16 atoms/cm³, waveform 214 is for N-region 146 doping concentration of 2e16 atoms/cm³, waveform 215 is for N-region 146 doping concentration of 1.5e16 atoms/cm³, waveform 216 is for N-region 146 doping concentration of 1e16 atoms/cm³, and waveform 218 is for N-region 146 doping concentration of 5e15 atoms/cm³. C_{OSS} increases with N-region 146 doping concentration. Accordingly, C_{OSS} and RONA is a competitive trade-off. When N-region 146 doping concentration is less than 1.5e16 atoms/cm³, BV decreases.

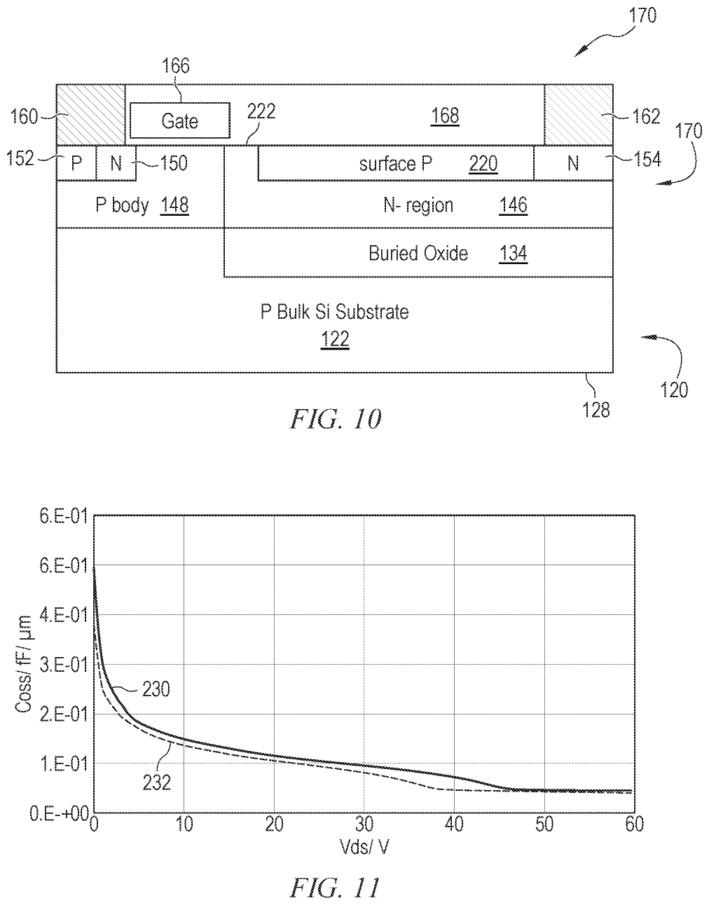

In another embodiment, continuing from FIG. 4g, P region 220 is formed at surface 222 in N-region 146 for higher breakdown voltage and low C_{OSS}, as shown in FIG. 10. In one embodiment, surface P region 220 has a doping concentration of 1.1e17 atoms/cm³. Surface P region 220 compensates for N-type charge in N-region 146. N-region 146 remains isolated from P bulk substrate 120 by insulating material 134.

FIG. 11 illustrates a graph of C_{OSS}, over a range of V_{DS}. Waveform 230 is with surface P region 220, and waveform 232 is without surface P region 220, similar to FIG. 4i. Surface P region 220 has a larger junction area and slightly larger C_{OSS}. At full depletion, waveforms 230 and 232 show about the same C_{OSS}. The additional PN junction at surface 222 increases C_{OSS}. RONA and C_{OSS} are in a competitive trade-off relationship. The structure in FIG. 4i or 12-15 is preferred to minimize C_{OSS}. The structure in FIG. 10 is preferred to minimize RONA.

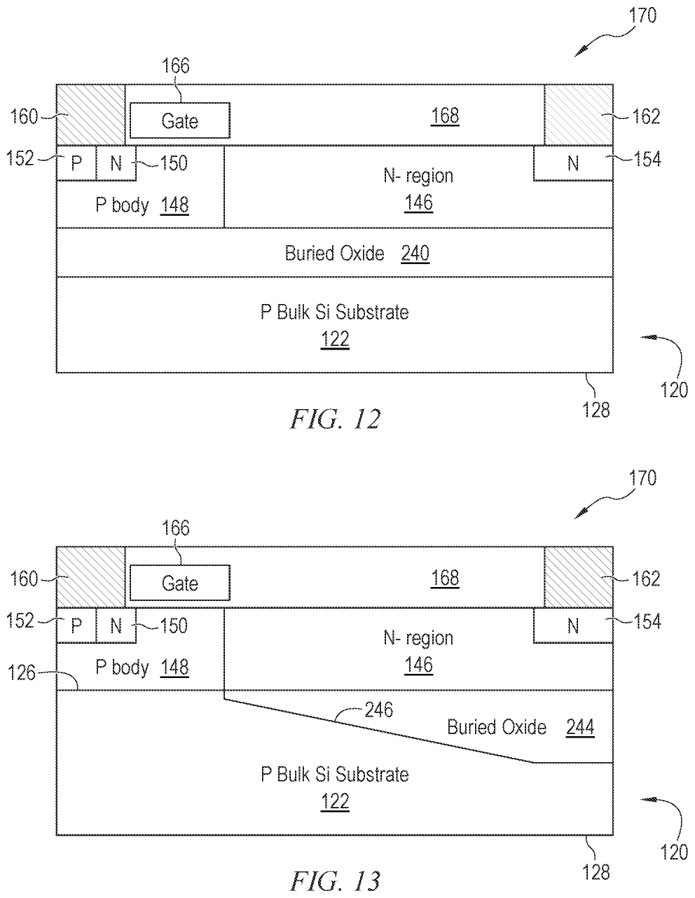

In another embodiment, similar to FIG. 4g, insulating material 240 extends across the entire width of cell 170, as shown in FIG. 12. In one embodiment, insulating material 240 is a buried oxide material having width W1 and thickness T2 of 1.0-5.0 μm, preferably 2.0 μm.

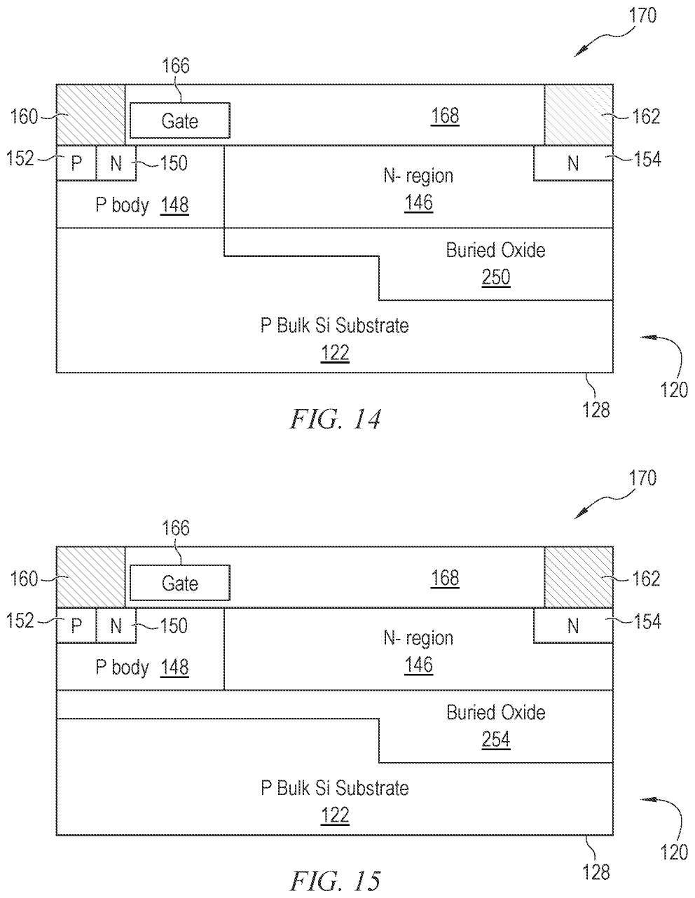

FIG. 13 shows an embodiment with insulating material 244 having linear slope 246 extending from the junction between P body 148 and N-region 146. FIG. 14 shows another embodiment with insulating material 250 having a first thickness of 0.5 μm and a second thickness of 2.0 μm with a step between the two thicknesses. FIG. 15 shows another embodiment with insulating material 254 having a first thickness of 0.5 μm and a second thickness of 2.0 μm with a step between the two thicknesses. In each case, the insulating material is a buried oxide material. A high breakdown voltage is achieved when N-region 146 doping concentration and oxide thickness are both optimally selected. For lower RONA, higher N-region 146 concentration is preferred, but with little or no effect from oxide thickness because oxide thickness affects two contradictory parameters. P bulk substrate 120 reduces the drain electric field by promoting depletion of N-layer 146 and, at the same time, induces an inversion layer which leads low breakdown voltage. The antinomy can be avoided by gradation of oxide thickness with linear slope 246, as in FIG. 13. FIG. 14 has similar effects and is more manufacturable than FIG. 13. Same for FIG. 15, although P bulk substrate 120 must be connected to P body 148 by other routing. N-region 146 remains isolated from P bulk substrate 120 by insulating material 134.

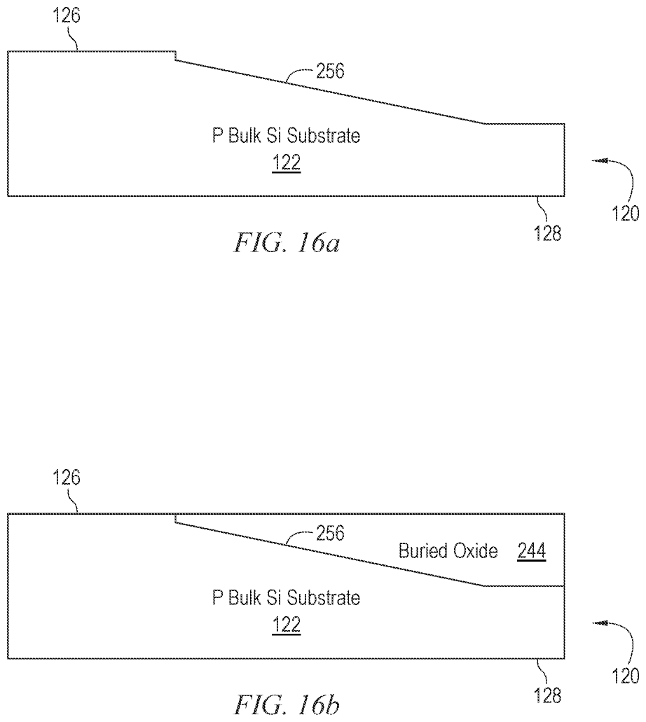

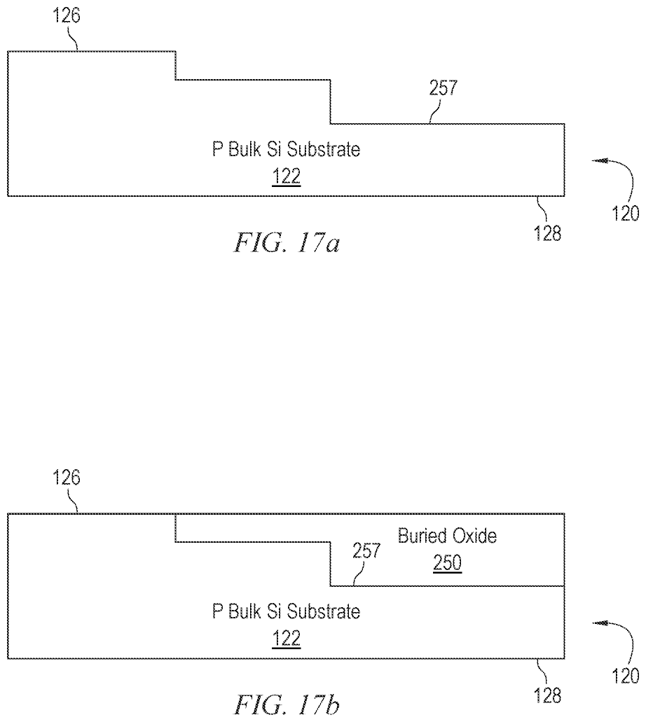

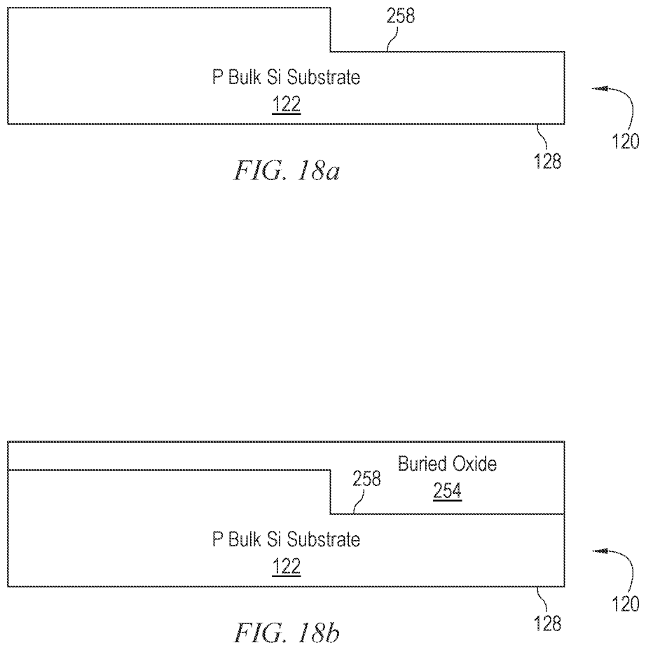

In terms of manufacturability, the linear slope 246 in FIG. 13 would require a correspondingly linear notch 256 in substrate 120, as shown in FIG. 16a and similar to FIGS. 4b-4c. In FIG. 16b, insulating material 244 is formed in notch 256. FIG. 16b, insulating material 244 is formed in notch 256. FIG. 13 shows cell 170 with insulating material 244 formed in notch 256 with slope 246. FIG. 17a shows notch 257 in substrate 120 corresponding to the step between the two thicknesses of insulating material in FIG. 14, similar to FIGS. 4b-4c. In FIG. 17b, insulating material 250 is formed in notch 257. FIG. 14 shows cell 170 with insulating material 250 formed in notch 257 with the step between the two thicknesses of insulating material. FIG. 18a shows notch 258 in substrate 120 corresponding to the step between the two thicknesses of insulating material in FIG. 15, similar to FIGS. 4b-4c. In FIG. 18b, insulating material 254 is formed in notch 258.

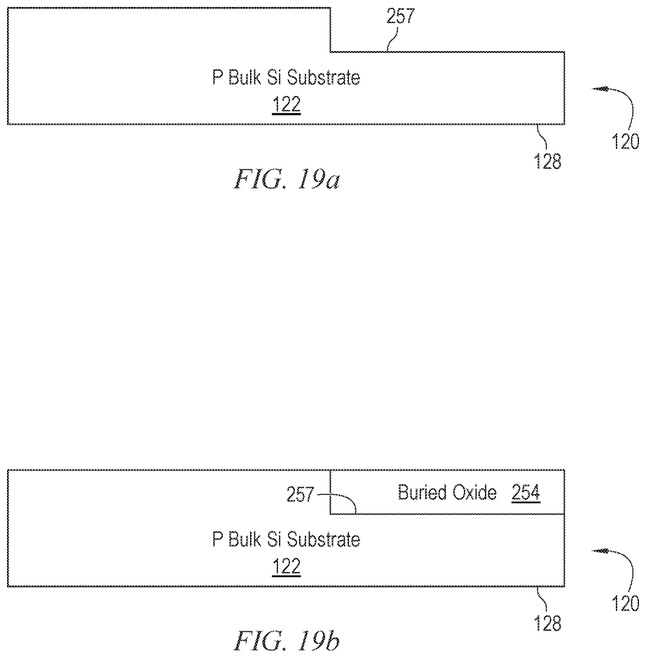

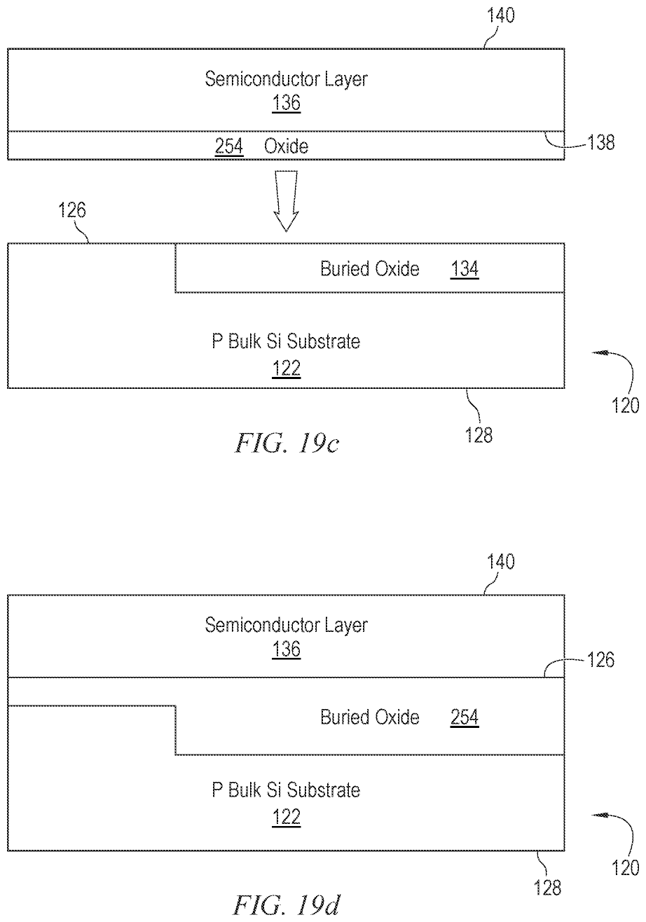

As an alternative in forming FIG. 15, FIG. 19a shows notch 257 in substrate 120 corresponding to the step between the two thicknesses of insulating material in FIG. 15, similar to FIGS. 4b-4c. In FIG. 19b, insulating material 254 is formed in notch 258. In FIG. 19c, additional insulating material 254 is formed over surface 138 of semiconductor layer 136. Semiconductor layer 136 is positioned over substrate 120 and insulating material 254 in notch 258, similar to FIG. 4d. In FIG. 19d, semiconductor layer 136 is bonded to substrate 120, similar to FIG. 4e. FIG. 15 shows cell 170 with insulating material 254 formed in notch 258 with the step between the two thicknesses of insulating material.

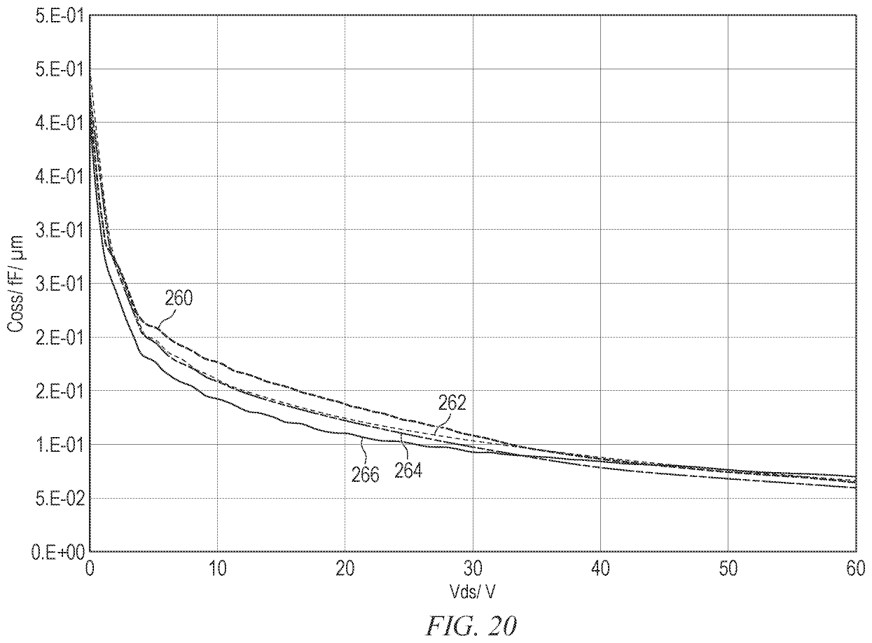

FIG. 20 illustrates a graph of C_{OSS}, over a range of V_{DS}. Waveform 260 is associated with FIG. 4i, waveform 262 is associated with FIG. 13, waveform 264 is associated with FIG. 14, and waveform 266 is associated with FIG. 15.

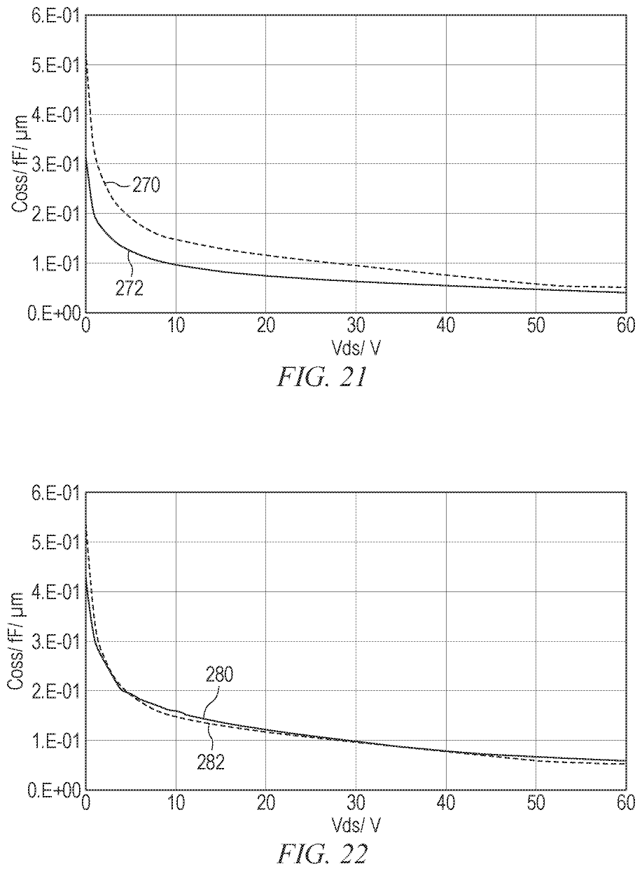

FIG. 21 illustrates a graph of C_{OSS}, over a range of V_{DS}. Waveform 270 represents the absence of buried oxide material, and waveform 272 is representative of FIG. 4i.

FIG. 22 illustrates a graph of C_{OSS}, over a range of V_{DS}. Waveform 280 represents the absence of buried oxide material, and waveform 282 is representative of FIG. 14.

In summary, insulating material 134 decreases C_{OSS}. The optimal buried oxide material thickness is determined by competitive relationship of depletion of N-region 146 and oxide capacitance. Output capacitance C_{OSS} reaches optimally minimal value when drain-source voltage V_{DS} reaches full depletion. Full depletion of V_{DS} occurs when N-region 146 doping concentration is minimal (high RONA) and when buried oxide material is thin (low BV). The sloped or stepped buried oxide material decreases RONA, while increasing C_{OSS} slightly, thus impacting the C_{OSS}/RONA trade-off. Surface P region 220 reduces RONA, with higher C_{OSS} for the additional PN junction.

While one or more embodiments of the present invention have been illustrated in detail, the skilled artisan will appreciate that modifications and adaptations to those embodiments may be made without departing from the scope of the present invention as set forth in the following claims.

What is claimed:

1. A power transistor including a plurality of cells, each cell comprising:
a substrate including a notch formed in the substrate;
an insulating material formed within the notch; and
a semiconductor layer formed over the substrate and insulating material, wherein the semiconductor layer includes a first type of semiconductor material and a second type of semiconductor material opposite the first type of semiconductor material to form the power transistor.

2. The power transistor of claim 1, wherein a width of the insulating material within the notch is less than a width of the semiconductor layer so that a portion of the substrate extends to the semiconductor layer.

3. The power transistor of claim 1, wherein the notch includes a slope.

4. The power transistor of claim 1, wherein the notch includes a step.

5. The power transistor of claim 1, wherein the insulating material includes a first thickness and a second thickness greater than the first thickness within the notch.

6. The power transistor of claim 1, wherein the insulating material includes an oxide.

7. A semiconductor device, comprising:
a substrate including a recessed area within the substrate;
an insulating material formed in the recessed area; and
a semiconductor layer formed over the substrate and insulating material, wherein the semiconductor layer includes a first type of semiconductor material and a second type of semiconductor material opposite the first type of semiconductor material.

8. The semiconductor device of claim 7, wherein a width of the insulating material within the recessed area is less than a width of the semiconductor layer so that a portion of the substrate extends to the semiconductor layer.

9. The semiconductor device of claim 7, wherein the recessed area includes a slope.

10. The semiconductor device of claim 7, wherein the recessed area includes a step.

11. The semiconductor device of claim 7, wherein the insulating material includes a first thickness and a second thickness greater than the first thickness within the recessed area.

12. The semiconductor device of claim 7, wherein the insulating material includes an oxide.

13. The semiconductor device of claim 7, wherein the semiconductor layer includes a cell of a power transistor.

14. A method of making a semiconductor device, comprising:
providing a substrate;
forming a recessed area within the substrate;
forming an insulating material in the recessed area; and
forming a semiconductor layer over the substrate and insulating material, wherein the semiconductor layer includes a first type of semiconductor material and a second type of semiconductor material opposite the first type of semiconductor material.

15. The method of claim 14, wherein a width of the insulating material within the recessed area is less than a width of the semiconductor layer so that a portion of the substrate extends to the semiconductor layer.

16. The method of claim 14, wherein the recessed area includes a slope.

17. The method of claim 14, wherein the recessed area includes a step.

18. The method of claim 14, wherein the insulating material includes a first thickness and a second thickness greater than the first thickness within the recessed area.

19. The method of claim 14, wherein the insulating material includes an oxide.

20. The method of claim 14, wherein the semiconductor layer includes a cell of a power transistor.
